(19) United States
(12) Patent Application Publication
(10) Pub. No.: US 2026/0304968 A1
(43) Pub. Date: Oct. 1, 2026

(54) SILICON DETECTOR ENABLED BY TUNNEL OXIDE PASSIVATING CONTACT

(71) Applicant: Georgia Tech Research Corporation, Atlanta, GA (US)

(72) Inventors: Yuguo Tao, Atlanta, GA (US); Mackenzie Duce, Atlanta, GA (US); Anna S. Erickson, Atlanta, GA (US)

(21) Appl. No.: 19/480,448

(22) PCT Filed: May 3, 2024
(86) PCT No.: PCT/US2024/027606

§ 371 Date: Oct. 31, 2025

Related U.S. Application Data
(60) Provisional application No. 63/500,306, filed on May 5, 2023.

(51) Int. Cl. H10F 30/221; H10F 71/00

(52) U.S. Cl. CPC H10F 30/221; H10F 71/128

(57) ABSTRACT

Systems, devices, and methods for manufacturing radiation detection devices. The radiation detection device comprises a silicon layer having at least a first side and a second side. The device may further comprise a first tunnel oxide layer having at least a first side and a second side. The second side of the first tunnel oxide layer may be disposed proximate to the first side of the silicon layer. The device may also comprise a first doped layer disposed proximate to the first side of the first tunnel oxide layer.

### CROSS-REFERENCE TO RELATED APPLICATIONS

This application claims the priority benefit of U.S. Provisional Patent Application Ser. No. 63/500,306, filed May 5, 2023, which is hereby incorporated by reference in its entirety.

### STATEMENT REGARDING FEDERALLY SPONSORED RESEARCH OR DEVELOPMENT

This invention was made with government support under grant/award number DE-NA0003921 awarded by the Department of Energy/National Nuclear Security Administration. The government has certain rights in the invention.

### BACKGROUND OF THE DISCLOSURE

### 1. Field of the Invention

The present invention relates generally to devices, systems, and methods of making silicon radiation detectors, and more particularly to silicon radiation detectors with tunnel oxide passivating contacts.

### 2. Description of Related Art

Silicon detector have become the predominant type of detector for may radiation applications, including heavy charged particles, alpha particles and fission fragments, X-ray spectroscopy in hospitals and health care centers, and personal monitors. These types of detectors these types of applications due to advantages of great energy resolution, fast timing characteristics, compactness, ruggedness, etc.

Traditional silicon detectors may comprise one or several different types of configurations: junction detector, surface barrier detector, passivated planar detector. The conventional p-n junction at the detector side of these conventional detectors is typically formed by ion-implanting phosphorus or arsenic dopants on high resistivity p-type float zone (FZ) silicon wafer, and then annealing at high temperature to eliminate the implantation damage and activate the dopants to create a heavily doped n⁺ layer. The p-n junction comprises a heavily doped layer on the opposite type of substrate is a rectifying contact, which acts as a blocking contact with a low minority carrier concentration inside. Along the back portion of these conventional silicon detectors, a heavily doped p⁺ layer is formed by implanting boron dopants and then annealing at high temperate to heal implantation damage and activate dopants. The heavily doped p⁺ layer creates a blocking contact at the rear side to suppress the leakage current because minority carriers travel across the junction. Therefore, when the charged particles strike the detector, electron-hole pairs are created along its path.

Any electrons created in the depleted region are swept toward the n-type side, and any holes are swept toward to the p-type side. Then electrons are collected through the front contact and transferred to the pre-amplifier, filter, and amplifier for signal processing, as shown in FIG. 1A (Prior Art). The incident radiation particle information can be extracted from the obtained electrical signal. But conventional silicon junction detectors encounter significant carrier recombination within the heavily dopes p⁺ and n⁺ layers, as well as beneath the metal contact regions, especially on the detector side, which is also known as “dead layer”. Silicon detectors, utilizing conventional p-n junctions or high-low junctions formed by heavily dopes p⁺ and n⁺ layers, dominate in radiation detection applications, but these silicon detectors suffer from Auger recombination, in the heavily doped layers, and metal-induced recombination beneath electrode contact area, such that, their detection performance is weakened.

These conventional systems and silicon detectors lack a high surface passivation layer and carrier selectivity that allows for efficient and selective transportation of one or more charge carriers. Thus, a need yet exists for innovative technologies that enable efficient and selective transportation of charge carries within a silicon detector using new approaches disclosed herein. In the case of silicon detectors, by selective transportation of charge carries, one can more accurately and efficiently detect electrical output.

### SUMMARY OF THE INVENTION

Briefly described, according to exemplary embodiments of the present invention, devices, systems, and method of an innovative system comprising a radiation detection device. In some exemplary embodiments, the present invention comprises at least one tunnel oxide layer configured to be a passivating contact.

In an exemplary embodiment of the present invention, a radiation detection device comprises a silicon layer having at least a first side and a second side. The radiation detection device may further comprise a first tunnel oxide layer having at least a first side and a second side. In various embodiments, the second side of the first tunnel oxide layer may be disposed proximate to the first side of the silicon layer. The radiation detection device may also comprise a first dope layer disposed proximate to the first side of the first tunnel oxide layer.

In various embodiments, the first side of the silicon layer may be disposed vertically opposite of the second side of the silicon layer.

In various embodiments, the radiation detection device may further comprise a second tunnel oxide layer having at least a first side and a second side. The first side of the second tunnel oxide layer may be disposed proximate to the second side of the silicon layer. In various embodiments, the radiation detection device may further comprise a second doped layer having at least a first side and a second side. The first side of the second doped layer may be disposed proximate to the second side of the second tunnel oxide. In various embodiments, the first doped layer is configured to be a polysilicon layer. In this example embodiment, the polysilicon layer may be configured to cause band bending in the silicon layer by creating an accumulation layer of charge carriers. In various embodiments, the second doped layer is configured to be a polysilicon layer. In this example embodiment, the polysilicon layer may be configured to cause band bending in the silicon layer by creating an accumulation layer of charge carriers.

In various embodiments, the first doped layer, the second doped layer, the first tunnel oxide layer, the second tunnel oxide layer, or a combination thereof may be configured to be thermally activated by thermal annealing. In an example embodiment, the thermal annealing temperatures range from approximately 500° C. to approximately 1200° C.

In various embodiments, the radiation detection device may further comprise a back contact. The back contact may be configured to be disposed proximate to the second side of the second doped layer. In various embodiments, the second doped layer may comprise a n-type dopant. The n-type dopant may be configured to be a phosphorous-dopant. In various embodiments, the second doped layer may comprise a p-type dopant. The p-type dopant may be configured to be a boron-dopant. In various embodiments, the second tunnel oxide layer may be configured to reduce charge carrier loss. In an example embodiment, the second tunnel oxide layer may be configured to transport majority charge carries via tunneling and block minority charge carriers. In various embodiments, the second tunnel oxide layer may be configured to reduce metal-induced electron recombination beneath a front contact and a back contact.

In various embodiments, the second tunnel oxide layer may comprise a uniform thickness. In various embodiments, the second tunnel oxide layer may comprise a thickness equal to or less than about 2 nm. In various embodiments, the first tunnel oxide layer and the second tunnel oxide layer may comprise equal thicknesses. In other embodiments, the first tunnel oxide layer and the second tunnel oxide layer may comprise unequal thicknesses. In various embodiments, the second doped layer may comprise a thickness equal to or less than about 30 nm.

In various embodiments, the first doped layer may comprise at least a first side and a second side. The second side of the first doped layer may be disposed proximate to the first side of the tunnel oxide layer. In various embodiments, the radiation detection device may further comprise a front contact. The front contact may be disposed proximate to the first side of the first doped layer. In various embodiments, the first doped layer comprises a n-type dopant. The n-type dopant may be configured to be a phosphorous-dopant. In various embodiments, the first doped layer may comprise a p-type dopant. The p-type dopant may be configured to be a boron-dopant. In various embodiments, the first tunnel oxide layer may be configured to reduce charge carrier loss. In an example embodiment, the first tunnel oxide layer may be configured to transport majority charge carriers via tunneling and block minority charge carriers. In various embodiments, the first tunnel oxide layer may be configured to reduce metal-induced electron recombination beneath a front contact and a back contact.

In various embodiments, the first tunnel oxide layer may comprise a uniform thickness. In various embodiments, the first tunnel oxide layer may comprise a thickness equal to or less than about 2 nm. In various embodiments, the first doped layer may comprise a thickness equal to or less than about 30 nm. In various embodiments, the radiation detection device may be configured to achieve an emitter saturation current density of approximately 1000 fA/cm².

In another exemplary embodiment of the present invention, a method is provided for manufacturing a radiation detection device. The method may comprise cleaning a silicon layer having at least a first side and a second side. The method may further comprise growing a first tunnel oxide layer having at least a first side and a second side. The second side of the first tunnel oxide layer may be disposed proximate to a first side of the silicon layer. The method may further comprise depositing a first doped layer proximate to the first side of the first tunnel oxide layer. The method may also comprise annealing the first tunnel oxide layer and the first doped layer.

In various embodiments, the first side of the silicon layer may be disposed vertically opposite of the second side of the silicon layer. In various embodiments, the method may further comprise growing a second tunnel oxide layer having at least a first side and a second side. The first side of the second tunnel oxide layer is disposed proximate to the second side of the silicon layer. In various embodiments, the first tunnel oxide layer and the second tunnel oxide layer may be grown simultaneously. In various embodiments, the first tunnel oxide layer and the second tunnel oxide layer may be grown individually.

In various embodiments, the method may further comprise depositing a second doped layer having at least a first side and a second side. The first side of the second doped layer may be disposed proximate to the second side of the second tunnel oxide layer. In various embodiments, the first doped layer may comprise at least a first side and a second side. The second side may be disposed proximate to the first side of the first tunnel oxide layer. In various embodiments, the method may further comprise depositing a front contact. The front contact may be disposed proximate to the first side of the first doped layer. In various embodiments, the method may further comprise depositing a back contact. The back contact may be disposed proximate to the second side of the second doped layer. In various embodiments, the second doped layer may comprise a thickness equal to or less than about 30 nm.

In various embodiments, the first dope layer may be configured to be a polysilicon layer. In an example embodiment, the polysilicon layer may be configured to cause band bending in the silicon layer by creating an accumulation layer of charge carriers. In various embodiments, the second doped layer may be configured to be a polysilicon layer. In an example embodiment, the polysilicon layer may be configured to cause band bending in the silicon layer by creating an accumulation layer of charge carriers. In various embodiments, the method may further comprise annealing, such that the first tunnel oxide layer, the first doped layer, the second tunnel oxide layer, the second doped layer, or a combination thereof are thermally activated. In an example embodiment, the annealing temperatures may range from approximately 500° C. to approximately 1200° C.

In various embodiments, the second doped layer may comprise a n-type dopant. The n-type dopant may be configured to be a phosphorous-dopant. In various embodiments, the second doped layer may comprise ap-type dopant. The p-type dopant is configured to be a boron-dopant. In various embodiments, the dopant precursor comprises PH₃. In various embodiments, dopant precursor comprises B₂H₆. In various embodiments, the second tunnel oxide layer may be configured to reduce charge carrier loss. In an example embodiment, the second tunnel oxide layer may be configured to transport majority charge carriers via tunneling and block minority charge carriers. In various embodiments, the second tunnel oxide layer may be configured to reduce metal-induce electron recombination beneath a front contact and a back contact. In various embodiments, the second tunnel oxide layer may comprise a uniform thickness. In various embodiments, the first tunnel oxide layer and the second tunnel oxide layer may comprise equal thicknesses. In various embodiments, the first tunnel oxide layer and the second tunnel oxide layer may comprise unequal thicknesses.

In various embodiments, the second doped layer may comprise a n-type dopant. The n-type dopant may be configured to be a phosphorous-dopant. In various embodiments, the second doped layer may comprise ap-type dopant. The p-type dopant is configured to be a boron-dopant. In various embodiments, the first tunnel oxide layer may be configured to reduce charge carrier loss. In an example embodiment, the first tunnel oxide may be configured to transport majority charge carrier via tunneling and block minority charge carriers. In various embodiments, the first tunnel oxide layer may be configured to reduce metal-induced electron recombination beneath a front contact and a back contact. In various embodiments, the first tunnel oxide layer may comprise a uniform thickness. In various embodiments, the first tunnel oxide layer may comprise a thickness equal to or less than about 2 nm. In various embodiments, the first doped layer may comprise a thickness equal to or less than about 30 nm.

In yet another exemplary embodiment of the present invention, a system is provided for detecting radiation. The radiation detection system may comprise a radiation detection device. The radiation detection device may comprise a silicon layer having at least a first side and a second side. The radiation detection device may further comprise a first tunnel oxide layer having at least a first side and a second side. In various embodiments, the second side of the first tunnel oxide layer may be disposed proximate to the first side of the silicon layer. The radiation detection device may also comprise a first dope layer disposed proximate to the first side of the first tunnel oxide layer. The system may also comprise a computing device. The computing device may be configured to be in communication with the radiation device.

In various embodiments, the first side of the silicon layer may be disposed vertically opposite of the second side of the silicon layer.

In various embodiments, the radiation detection device may further comprise a second tunnel oxide layer having at least a first side and a second side. The first side of the second tunnel oxide layer may be disposed proximate to the second side of the silicon layer. In various embodiments, the radiation detection system may further comprise a second doped layer having at least a first side and a second side. The first side of the second doped layer may be disposed proximate to the second side of the second tunnel oxide. In various embodiments, the first doped layer is configured to be a polysilicon layer. In this example embodiment, the polysilicon layer may be configured to cause band bending in the silicon layer by creating an accumulation layer of charge carriers. In various embodiments, the second doped layer is configured to be a poly silicon layer. In this example embodiment, the polysilicon layer may be configured to cause band bending in the silicon layer by creating an accumulation layer of charge carriers.

In various embodiments, the first doped layer, the second doped layer, the first tunnel oxide layer, the second tunnel oxide layer, or a combination thereof may be configured to be thermally activated by thermal annealing. In an example embodiment, the thermal annealing temperatures range from approximately 500° C. to approximately 1200° C.

In various embodiments, the radiation detection device may further comprise a back contact. The back contact may be configured to be disposed proximate to the second side of the second doped layer. In various embodiments, the second doped layer may comprise a n-type dopant. The n-type dopant may be configured to be a phosphorous-dopant. In various embodiments, the second doped layer may comprise a p-type dopant. The p-type dopant may be configured to be a boron-dopant. In various embodiments, the second tunnel oxide layer may be configured to reduce charge carrier loss. In an example embodiment, the second tunnel oxide layer may be configured to transport majority charge carries via tunneling and block minority charge carriers. In various embodiments, the second tunnel oxide layer may be configured to reduce metal-induced electron recombination beneath a front contact and a back contact.

In various embodiments, the second tunnel oxide layer may comprise a uniform thickness. In various embodiments, the second tunnel oxide layer may comprise a thickness equal to or less than about 2 nm. In various embodiments, the first tunnel oxide layer and the second tunnel oxide layer may comprise equal thicknesses. In other embodiments, the first tunnel oxide layer and the second tunnel oxide layer may comprise unequal thicknesses. In various embodiments, the second doped layer may comprise a thickness equal to or less than about 30 nm.

In various embodiments, the first doped layer may comprise at least a first side and a second side. The second side of the first doped layer may be disposed proximate to the first side of the tunnel oxide layer. In various embodiments, the radiation detection device may further comprise a front contact. The front contact may be disposed proximate to the first side of the first doped layer. In various embodiments, the first doped layer comprises a n-type dopant. The n-type dopant may be configured to be a phosphorous-dopant. In various embodiments, the first doped layer may comprise a p-type dopant. The p-type dopant may be configured to be a boron-dopant. In various embodiments, the first tunnel oxide layer may be configured to reduce charge carrier loss. In an example embodiment, the first tunnel oxide layer may be configured to transport majority charge carriers via tunneling and block minority charge carriers. In various embodiments, the first tunnel oxide layer may be configured to reduce metal-induced electron recombination beneath a front contact and a back contact.

In various embodiments, the first tunnel oxide layer may comprise a uniform thickness. In various embodiments, the first tunnel oxide layer may comprise a thickness equal to or less than about 2 nm. In various embodiments, the first doped layer may comprise a thickness equal to or less than about 30 nm. In various embodiments, the radiation detection device may be configured to achieve an emitter saturation current density of approximately 1000 fA/cm².

These and other aspects, features, and benefits of the claimed invention(s) will become apparent from the following detailed written description of the preferred embodiments and aspects taken in conjunction with the following drawings, although variations and modifications thereto may be affected without departing from the spirit and scope of the novel concepts of the disclosure.

### BRIEF DESCRIPTION OF THE DRAWINGS

Implementations, features, and aspects of the disclosed technology are described in detail herein and are considered a part of the claimed disclosed technology. Other implementations, features, and aspects can be understood with reference to the following detailed description, accompanying drawings, and claims. Wherever possible, the same reference numbers are used throughout the drawings to refer to the same or like members of an embodiment. Reference will now be made to the accompanying figures and flow diagrams, which are not necessarily drawn to scale.

FIG. 1A provides a schematic illustration of a convention silicon junction detector known in the prior art.

FIG. 1B provides a schematic illustration of a conventional p-n junction with heavily doped layers of n⁺ known in the prior art.

FIG. 1C provides a schematic illustration of a conventional p-n junction with heavily doped layers of p⁺ known in the prior art.

FIG. 2 provides a schematic illustration of an example silicon detector comprising tunnel oxide layers in accordance with various embodiments of the present disclosure.

FIG. 3A provides a schematic band diagram of tunnel oxide layer with doped layer of n⁺ polysilicon layer in accordance with various embodiments of the present disclosure.

FIG. 3B provides a schematic band diagram of tunnel oxide layer with doped layer of p⁺ polysilicon layer in accordance with various embodiments of the present disclosure.

FIG. 4A provides a schematic illustration of a portion of an example fabrication process of a radiation detection device in accordance with various embodiments of the present disclosure.

FIG. 4B provides a schematic illustration of a portion of an example fabrication process of a radiation detection device in accordance with various embodiments of the present disclosure.

FIG. 4C provides a schematic illustration of a portion of an example fabrication process of a radiation detection device in accordance with various embodiments of the present disclosure.

FIG. 4D provides an example flow diagram illustrating a method for fabricating a radiation detection device in accordance with various embodiments of the present disclosure.

FIG. 5 provides a schematic illustration of a pinhole within a radiation detection device in accordance with various embodiments of the present disclosure.

FIG. 6 illustrates a plot of J₀ of n-type tunnel oxide layer as a function of annealing, including the J₀ without tunnel oxide layer temperature, in accordance with various embodiments of the present disclosure.

FIG. 7A provides a plot comparison of measured J₀ as a function of the sheet resistance of conventional n⁺ layers in accordance with various embodiments of the present disclosure.

FIG. 7B provides a plot comparison of measured J₀ as a function of the sheet resistance of conventional p⁺ layers in accordance with various embodiments of the present disclosure.

FIG. 8 provides a schematic cross-sectional illustration comparing conventional silicon detectors to silicon detectors with tunnel oxide passivating contact in accordance with various embodiments of the present disclosure.

FIG. 9A illustrates a block diagram of an example system for radiation detection in accordance with various embodiments of the present disclosure.

FIG. 9B illustrates a block diagram of an example computing device in accordance with various embodiments of the present disclosure.

### DETAILED DESCRIPTION OF THE INVENTION

Although preferred exemplary embodiments of the disclosure are explained in detail, it is to be understood that other exemplary embodiments are contemplated. Accordingly, it is not intended that the disclosure is limited in its scope to the details of construction and arrangement of components set forth in the following description or illustrated in the drawings. The disclosure is capable of other exemplary embodiments and of being practiced or carried out in various ways. Also, in describing the preferred exemplary embodiments, specific terminology will be resorted to for the sake of clarity.

To facilitate an understanding of the principles and features of the present disclosure, various illustrative embodiments are explained below. The components, steps, and materials described hereinafter as making up various elements of the embodiments disclosed herein are intended to be illustrative and not restrictive. Many suitable components, steps, and materials that would perform the same or similar functions as the components, steps, and materials described herein are intended to be embraced within the scope of the disclosure. Such other components, steps, and materials not described herein can include, but are not limited to, similar components or steps that are developed after development of the embodiments disclosed herein.

As used in the specification and the appended claims, the singular forms “a,” “an” and “the” include plural referents unless the context clearly dictates otherwise.

Also, in describing the preferred exemplary embodiments, terminology will be resorted to for the sake of clarity. It is intended that each term contemplates its broadest meaning as understood by those skilled in the art and includes all technical equivalents which operate in a similar manner to accomplish a similar purpose.

Ranges can be expressed herein as from “about” or “approximately” one particular value and/or to “about” or “approximately” another particular value. When such a range is expressed, another exemplary embodiment includes from the one particular value and/or to the other particular value.

Similarly, as used herein, “substantially free” of something, or “substantially pure”, and like characterizations, can include both being “at least substantially free” of something, or “at least substantially pure”, and being “completely free” of something, or “completely pure”.

By “comprising” or “containing” or “including” is meant that at least the named compound, member, particle, or method step is present in the composition or article or method, but does not exclude the presence of other compounds, materials, particles, method steps, even if the other such compounds, material, particles, method steps have the same function as what is named.

Mention of one or more method steps does not preclude the presence of additional method steps or intervening method steps between those steps expressly identified. Similarly, it is also to be understood that the mention of one or more components in a device or system does not preclude the presence of additional components or intervening components between those components expressly identified.

The materials described as making up the various members of the invention are intended to be illustrative and not restrictive. Many suitable materials that would perform the same or a similar function as the materials described herein are intended to be embraced within the scope of the invention. Such other materials not described herein can include, but are not limited to, for example, materials that are developed after the time of the development of the invention.

Reference will now be made in detail to exemplary embodiments of the disclosed technology, examples of which are illustrated in the accompanying drawings and disclosed herein. Wherever convenient, the same references numbers will be used throughout the drawings to refer to the same or like parts.

In various embodiments, an example radiation detection device as described herein may be configured to comprise at least one tunnel oxide layer to act as a passivate contact within a radiation detection device. In various embodiments, a radiation detection device may comprise a first tunnel oxide layer, a first doped layer, and a silicon layer. In various embodiments, a radiation detection device may further comprise a second tunnel oxide later, a second doped layer, a front contact, and/or a back contact. In various embodiments, the first tunnel oxide layer and/or the second tunnel oxide layer may be configured to reduce charge carrier loss of a radiation detection device. In various embodiments, the first tunnel oxide layer and/or the second tunnel oxide layer may be configured to transport majority charge carriers via tunneling and block minority charge carriers. In some embodiments, the first tunnel oxide and/or the second tunnel oxide may be configured to reduce metal-induced electron recombination beneath the front contact and the back contact.

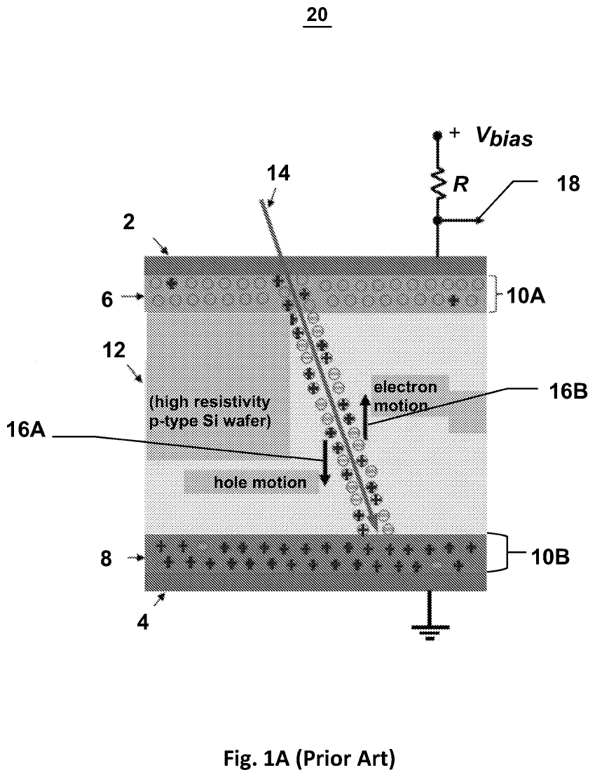

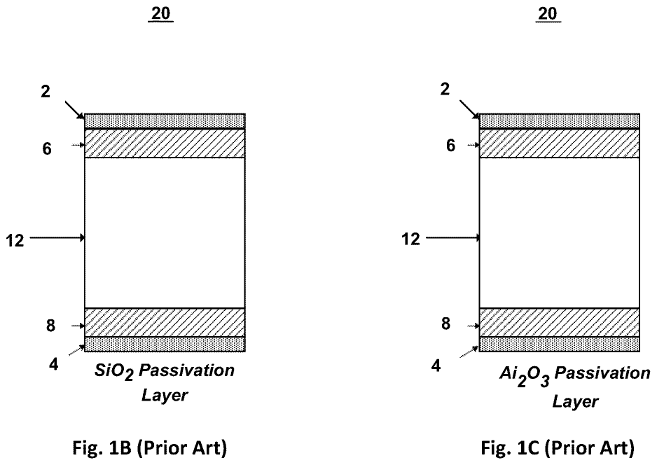

FIGS. 1A-IC illustrate exemplary configurations of prior art silicon radiation detection device in accordance with various embodiments. An example silicon detection device 20 comprises a p-n junction at the detector side of the silicon detection device 20. In various embodiments, these conventional detection devices are configured to have a first heavily doped layer 6 and a second heavily doped layer 8 disposed on opposite sides of a float zone silicon wafer 12. The first heavily doped layer 6 and the second heavily doped layer 8 are configured to be dead layers in conventional radiation detection devices. The first heavily doped layer 6 and the second heavily doped layer 8 are configured to be annealed at high temperatures to eliminate implantation damages. The first heavily doped layer 6 may be configured to be n⁺-layer, wherein the n⁺-layer is configured to try to block low minority carrier concentration inside. The first heavily dope layer 6 is configured to be capped by a front contact 2. The second heavily doped 8 layer may be configured to be p⁺-layer, wherein the p⁺-layer is configured to try to create a blocking contact at the rear side to suppress the leakage current because of minority carriers travel across the junction. The second heavily dope layer 6 may be capped by a back contact 2.

With further reference to FIGS. 1A-IC, in an instance a charged particle travels through the first heavily doped layer 6, n⁺ layer, at the detector side, the charged particle creates electron-hole pairs 14. The generated hole carriers in traditional radiation detection devices 14 can quickly recombine with surrounding high-concentration electrons and annihilate prior to traversing 16A, 16B the depleted region (e.g., silicon wafer 12), due to Auger recombination. The Auger recombination results in a low energy resolution because a part of charge particle energy is just lost when the created electron-hole pairs quickly recombine within this dead layer 10A, 10B and do not contribute to the output electrical signal. Traditional radiation detection devices further suffer from metal-induced trapping centers and recombination centers at the contact regions induce a high recombination velocity, severely deteriorating the detector's energy resolution. Similarly, as a charged particle penetrate all the way to the back side of detector and reach to the p⁺ layer to create electron-hole pairs, the generated electrons further configured to quickly recombine with surrounding high-concentration holes and annihilate prior to traversing the depleted region toward the n-type side, due to a high recombination velocity caused by severe Auger recombination.

Additionally, in the prior art devices of FIGS. 1A-1C, the metal-induced trapping centers and recombination centers at the contact regions induce a high recombination velocity, which severely deteriorates the detector's energy resolution. Similarly, in the prior art device of FIG. 1A, as charged particles penetrate all the way to the back side of detector and reach to the p⁺ layer to create electron-hole pairs, the generated electrons also quickly recombine with surrounding high-concentration holes and annihilate prior to traversing the depleted region toward the n-type side. This high recombination velocity is also caused by severe Auger recombination. Moreover, in the prior art device of FIG. 1A, the metal-induced recombination at the rear contact regions causes an enormous carrier loss. As a consequence, the energy resolution of these conventional silicon junction detectors is notably reduced due to the charge carrier loss within the heavily doped p⁺ and n⁺ layers as well as at the metal contact regions.

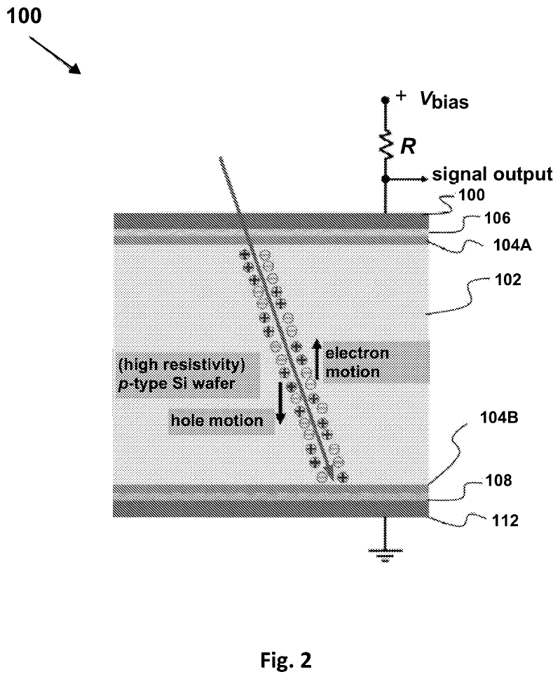

FIG. 2 illustrates an exemplary radiation detection device with a passivating contact (e.g., tunnel oxide layer) in accordance with various embodiments of the present disclosure. In various embodiments, the radiation detection device 100 comprises at least one improved surface passivation (e.g., at least one tunnel oxide layer) configured to improve the charge carrier selectivity of the radiation detection device 100. In various embodiments, the radiation detection device 100 comprises at least a silicon layer 102, a first tunnel oxide layer 104A, and/or a first doped layer 106. In various embodiments, the radiation detection device 100 may further comprise a second tunnel oxide layer 104B and/or a second doped layer 108. In one or more embodiments, the radiation detection device may further comprise one or more additional tunnel oxide layer (not depicted) and/or one or more additional doped layer (not depicted). As illustrated in FIG. 2, the silicon layer 102 (e.g., silicon wafer) may comprise at least a first side and a second side. The first side of the silicon layer may be disposed vertically opposite to the second side of the silicon layer. In other embodiments, the first side of the silicon layer may be disposed horizontally opposite to the second side of the silicon layer. In various embodiments, the silicon layer 102 may comprise a crystalline silicon semiconductor wafer (c-Si). The crystalline silicon semiconductor wafer (e.g., silicon wafer) may undergo one or more microfabrication processes, such as doping, ion implantation, etching, thin-film deposition, photolithography, and the like. In one or more embodiments, the silicon layer 102 may not be pure silicon, but is instead formed with an initial impurity doping concentration between 10¹³ and 10¹⁶ atoms per cm³ of boron, phosphorus, arsenic, or antimony which is added to the melt and defines the wafer as either bulk n-type or p-type.

In various embodiments, the radiation detection device 100 may be used for measurement applications including, for example, heavy charged particles (e.g., alpha particles, fission fragments, and the like), for general charged particle spectroscopy, alpha particle spectroscopy, alpha particle and fission fragment spectroscopy, X-ray spectroscopy, and the like. Such radiation detection device 100 are useful for hospitals and health care centers. In some embodiments, radiation detection device 100 may also be used as a personal monitor for radiation.

In various embodiments, the first tunnel oxide layer 104A may be configured to function as a tunneling layer to allow one or more charge carriers through. In one or more embodiments, the first tunnel oxide layer 104A may comprise a thickness of tunneling oxide. The thickness of a tunneling oxide may be less than 2 nm (e.g., about 1.5 nm). In various embodiments, the thickness may impact the electrical properties and efficiency of the radiation detection device 100. The first tunnel oxide layer 104A and/or the second tunnel oxide layer 104B (e.g., tunneling oxide layers) may be deposited (e.g., grown, placed, connected, etc.) using suitable fabrication methods such as chemical, ozone, thermal, atomic layer deposition (ALD), chemical vapor deposition (CVD), plasma enhanced chemical vapor deposition (PECVD) oxidation to deposit the thin SiOx layer over the silicon layer 102.

With further reference to FIG. 2, in various embodiments, the first tunnel oxide layer 104A may comprises a uniform thickness. In some embodiments, the thickness of the first tunnel oxide layer 104A may be less than or equal to 2 nm. In various embodiments, the first tunnel oxide layer 104A (e.g., first tunnel oxide passivating contact) comprises at least a first side and a second side, such that, the first side of the first tunnel oxide layer 104A is disposed vertically opposite the second side. In other embodiments, the first side of the first tunnel oxide layer may be disposed horizontally opposite to the second side of the first tunnel oxide layer. The first tunnel oxide layer 104A is configured to be disposed proximate to the first side of the silicon layer 102, such that the second side of the first tunnel oxide layer 104A is configured to disposed proximate to the first side of the silicon layer.

In various embodiments, the first tunnel oxide layer 104A (e.g., tunnel oxide passivating contact) may be utilized by a radiation detection device 100 to eliminate at least one heavily doped dead layer (p⁺ and/or n⁺ layers) of traditional radiation detection devices. The first tunnel oxide layer 104A may be further configured to assist in reducing charge carrier loss within the radiation detection device. In various embodiments, the first tunnel oxide layer 104A may additionally and/or alternatively assist in transporting majority charge carriers via tunneling within the radiation detection device and block minority charge carriers. Additionally and/or alternatively, the first tunnel oxide layers 104A may be configured to reduce the metal-induced recombination beneath metal contact regions (e.g., front contact 110 and back contact 112, depicted in FIG. 2).

With even further reference to FIG. 2, in various embodiments, the first doped layer 106 of a radiation detection device 100 may comprise at least a first side and a second side. In various embodiments, the first side of the first doped layer may be disposed vertically opposite to the second side of the first doped layer. In other embodiments, the first side of the first doped layer may be disposed horizontally opposite to the second side of the first doped layer. The first doped layer 106 may be disposed proximate to the first side of the first tunnel oxide layer 104A, such that the second side of the first doped layer at least partially connects with the first side of the first tunnel oxide layer 104A. In various embodiments, the first doped layer 106 may be a polysilicon layer. The polysilicon layer can be configured to cause band bending in the silicon layer by creating an accumulation layer of charge carriers. In various embodiments, the first doped layer 106 may comprise a one or more type of dopant. The one or more type of dopant may be a n⁺ type dopant belonging to group V, such as, for example, nitrogen (N), phosphorus (P), arsenic (As), antimony (Sb), bismuth (Bi), and lithium (Li). In other embodiments, the dopant precursor can include phosphine (PH₃), triphenylphosphine (TPP), P-ions, phosphoric acid (H₃PO₄), trimethylammonium, arsine (AsH₃) and the like. In various embodiments, the one or more dopant of the first doped layer 106 may be a p⁺ type dopant may be configured to belong to group III, such as boron (B), aluminum (Al), gallium (Ga), and/or indium (In). In various embodiments, the dopant precursor may include trimethyl borate, diborane (B₂H₆), aluminum chloride (AlCl₃), aluminum acetate basic hydrate [(CH₃CO₂)AlOH·H₂O], and/or the like.

In various embodiments, a n-type tunnel oxide layer (e.g., tunnel oxide passivating contact) can be configured to passivate the silicon layer and decrease hole recombination near the front contact 110. By decreasing hole recombination, the tunnel oxide layer can cause lower amount of recombination current density at the surface and lower surface leakage current. In one or more embodiments, the n-type tunnel oxide layer may be further configured to facilitate electrons to pass through the silicon layer by means of tunneling, such that the tunneling enables one dimensional current flow and low effective contact resistivity.

In various embodiments, the first doped layer 106 may be deposited on the first tunnel oxide layer 104A via various deposition methods, including, but not limited to, atomic layer deposition (ALD), chemical vapor deposition (CVD), plasma enhanced chemical vapor deposition (PECVD) fabrication methods, the like, and combinations thereof. In various embodiments, the thickness of the first doped layer 106 can range from about 1 nm to about 30 nm, preferably less than 20 nm. In various embodiments, the radiation detection system 100 may further comprise a front contact 110. The front contact 110 can be disposed proximate to the first side of the first doped layer 106. In various embodiments, the front contact 110 can be configured to contact the first side of the first doped layer 106 at least partially. In some embodiments, the front contact 110 may comprise a metal selected from at least one of the following: Y, Sc, Ag, Al, Ti, Au, Ni, or a combination thereof. In various embodiments, the front contact 110 can comprise a predetermined thickness in order to achieve a desired function.

With even further reference to FIG. 2, in various embodiments, the radiation detection device 100 may further comprise a second tunnel oxide layer 104B. In various embodiments, the second tunnel oxide layer 104B can be configured to comprise a uniform thickness. In some embodiments, the thickness of the second tunnel oxide layer 104B may be less than or equal to 2 nm. In one or more embodiments, the first tunnel oxide layer 104A and the second tunnel oxide layer 104B can comprise equal thicknesses. In other embodiments, the first tunnel oxide layer 104A and the second tunnel oxide layer 104B can comprise unequal thicknesses. In various embodiments, the second tunnel oxide layer 104B (e.g., second tunnel oxide passivating contact) can comprise at least a first side and a second side, such that the first side of the second tunnel oxide layer 104B can be disposed vertically opposite to the second side. In other embodiments, the first side of the second tunnel oxide layer may be disposed horizontally opposite to the second side of the second tunnel oxide layer. The second tunnel oxide layer 104B can be configured to be disposed proximate to the second side of the silicon layer 102, such that the first side of the second tunnel oxide layer 104B can be configured to be disposed proximate to the second side of the silicon layer. In various embodiments, the first side of the second tunnel oxide layer 104B may at least partially contact the second side of the silicon layer.

In various embodiments, the second tunnel oxide layer 104B (e.g., second tunnel oxide passivating contact) may be utilized for a radiation detection device 100 to eliminate one or more additional heavily doped dead layer at least partially (p⁺ and/or n⁺ layers) of traditional radiation detection devices. The second tunnel oxide layer 104B may be further configured to assist in reducing charge carrier loss within the radiation detection device. In various embodiments, the second tunnel oxide layer 104B may be configured to further assist in transporting majority charge carriers via tunneling within the radiation detection device and block minority charge carriers with the first tunnel oxide layer 104A. Additionally and/or alternatively, the second tunnel oxide layers 104B may be configured to reduce the metal-induced recombination beneath metal contact regions (e.g., front contact 110 and back contact 112).

With even further reference to FIG. 2, in various embodiments, the second doped layer 108 of a radiation detection device 100 comprises at least a first side and a second side. In various embodiments, the first side of the second doped layer may be disposed vertically opposite to the second side of the second doped layer. In other embodiments, the first side of the second doped layer may be disposed horizontally opposite to the second side of the second layer. The second doped layer 108 can be configured to be disposed proximate to the second side of the second tunnel oxide layer 104B, such that the first side of the second doped layer 108 at least partially connects with the second side of the second tunnel oxide layer 104B. In various embodiments, the second doped layer 108 may be a polysilicon layer. The polysilicon layer can be configured to cause band bending in the silicon layer by creating an accumulation layer of charge carriers. In various embodiments, the second doped layer 108 may comprise a one or more type of dopant. The one or more type of dopant may be a n⁺ type dopant belonging to group V, such as, for example, nitrogen (N), phosphorus (P), arsenic (As), antimony (Sb), bismuth (Bi), and lithium (Li). In other embodiments, the dopant precursor can include phosphine (PH₃), triphenylphosphine (TPP), P-ions, phosphoric acid (H₃PO₄), trimethylammonium, arsine (AsH₃) and the like. In various embodiments, the one or more dopant of the second doped layer 108 may be a p⁺ type dopant may be configured to belong to group III, such as boron (B), aluminum (Al), gallium (Ga), and/or indium (In). In various embodiments, the dopant precursor may include trimethyl borate, diborane (B₂H₆), aluminum chloride (AlCl₃), aluminum acetate basic hydrate [(CH₃CO₂)AlOH·H₂O], and/or the like.

In various embodiments, the second doped layer 108 may be deposited beneath the lowermost surface of the second tunnel oxide layer 104B via many different deposition methods, including, but not limited to atomic layer deposition (ALD), chemical vapor deposition (CVD), plasma enhanced chemical vapor deposition (PECVD), the like, and combination thereof. In various embodiments, the thickness of the second doped layer 108 can range from about 1 nm to about 30 nm, preferably less than 20 nm. In various embodiments, the radiation detection device 100 may further comprise a back contact 112. The back contact 112 can be disposed proximate to the second side of the second doped layer 106. In various embodiments, the back contact 112 can be configured to contact the second side of the second doped layer 108 at least partially. In some embodiments, the back contact 112 may comprise a metal selected from at least one of the following: Y, Sc, Ag, Al, Ti, Au, Ni, or a combination thereof.

In various embodiments, the radiation detection device 100 can be configured to be capped with a second doped layer 108. In various embodiments, the second dopant can be ap, type dopant may be configured to belong to group III, such as boron (B), aluminum (Al), gallium (Ga), and indium (In). In various embodiments, the dopant precursor may include trimethyl borate, diborane (B₂H₆), aluminum chloride (AlCl₃), aluminum acetate basic hydrate [(CH₃CO₂)AlOH·H₂O], and the like. The second doped layer 108 can be deposited via atomic layer deposition (ALD), chemical vapor deposition (CVD), plasma enhanced chemical vapor deposition (PECVD) fabrication methods. In various embodiments, the thickness of the second doped layer 108 can range from about 1 nm to about 30 nm, preferably less than 20 nm. In various embodiments, the radiation detection device may further comprise back contact 112, such that the back contact 112 may be configured to be positioned over the second doped layer 108. In various embodiments, the back contact 112 may be a metal selected from Y, Sc, Ag, Al, Ti, Au, or Ni. In various embodiments, the second doped layer 108 capping the tunnel oxide layer (e.g., first ultra-thin oxide layer) on the second side of the silicon layer 102 can form ap-type tunnel oxide passivating contact. In various embodiments, the back contact 112 can comprise a predetermined thickness in order to achieve a desired function.

In various embodiments, the p-type tunnel oxide passivating contact (e.g., first tunnel oxide layer and/or second tunnel oxide layer) may be configured to passivate a bottom surface of the radiation device 100 and suppress electron recombination near the front contact 110 and/or back contact 112. In various embodiments, the p-type tunnel oxide passivating contact (e.g., first tunnel oxide layer and/or second tunnel oxide layer) may be configured to passivate a top surface and/or bottom surface of the radiation device 100 and suppress electron recombination near the front contact 110 and/or back contact 112. In various embodiments, the n-type tunnel oxide passivating contact (e.g., first tunnel oxide layer and/or second tunnel oxide layer) may be configured to passivate a bottom surface of the radiation device 100 and suppress electron recombination near the back contact 112. In various embodiments, the n-type tunnel oxide passivating contact (e.g., first tunnel oxide layer and/or second tunnel oxide layer) may be configured to passivate a top surface and/or bottom surface of the radiation device 100 and configured to suppress electron recombination near the front contact 110 and/or back contact 112. In various embodiments, the p-type and/or the n-type structure (e.g., first tunnel oxide layer and/or second tunnel oxide layer) may be configured to prevent low leakage current at the top surface and/or the bottom surface of the radiation device 100 and/or simultaneously allows holes to tunnel through. In various embodiments, the radiation detection device 100 can be further configured to lower noise levels and higher energy resolution. In various embodiments, the radiation detection device 100 of the present application can be further configured to be used as a charged particle spectroscopy and/or passivated planar detectors.

In various embodiments, to compare charge carrier recombination loss between the conventional p-n junction and the tunnel oxide layer(s), the quasi-steady-state photoconductance (QSSPC) characterization technique and the contactless photoconductivity decay method may be used to quantify the emitter saturation current density (J₀) from the carrier lifetime measurement. J₀ was extracted from the slope of linear fit of the measured Auger-corrected inverse effective lifetime as a function of the injection level, by Equation (1):

$$\frac{1}{{τ}_{eff}} - \frac{1}{{τ}_{Auger}} = \frac{1}{{τ}_{S R H}} + 2 * \frac{{J}_{0} ( {N}_{d} + Δ n )}{q {n}_{i}^{2} W} \qquad Eq . 1$$

where W is the silicon wafer substrate thickness, Δn the excess carrier density, q the electron charge, nᵢ the intrinsic carrier concentration of crystalline silicon wafer, Nd the bulk doping level, τ_{SRH} the defect-related bulk lifetime-Shockley-Read-Hall (SRH) recombination in the bulk, τ_{Auger} the intrinsic Auger lifetime, and eff the measured effective excess carrier lifetime. Lower J₀ value indicates higher carrier lifetime due to less carrier recombination, including Auger recombination in the heavily doped layer and the surface recombination.

As shown in FIG. 2, in order to fabricate high energy resolution detectors (e.g., radiation detection device 100) with low bulk leakage current, the radiation detection device can be configured to comprise a high purity (intrinsic or undoped) silicon layer (e.g., silicon wafer) with resistivity over 10,000 Ωcm. In various embodiments, the high resistivity silicon layer may comprise a predetermined resistivity for a given applied bias voltage. In various embodiments, the depletion region width may be maximized by minimizing the silicon substrate's doping concentration. In addition, the applied reverse bias voltage needed to be higher than the depletion voltage (V_{d}), which is calculated by Equation 2:

$${V}_{d} = \frac{q N {T}^{2}}{2 ∈} \qquad Eq . 2$$

where q is the electron charge, N is the dopant concentration of high resistivity silicon wafer, T is the wafer thickness, and E is the dielectric constant of silicon. To avoid an undepleted region, the depletion region of a silicon layer (e.g., silicon wafer) can be configured to extend from the top surface of the silicon layer and the bottom surface of the silicon layer to achieve a fully depleted configuration. An undepleted region represented dead layer, such that no charge carrier was collected because there was no electric field. Furthermore, the orientation of the path of a charge particle with respect to the silicon layers crystal axes can have a significant impact on the rate of energy loss of the charged particle. Particles traveling parallel to silicon layer crystal planes may comprise a lower energy loss than that of particles directed in random particles, termed “channeling”. Therefore, high-resistivity silicon layers with crystal orientation may be used to minimize the tendency for incident particles to channel.

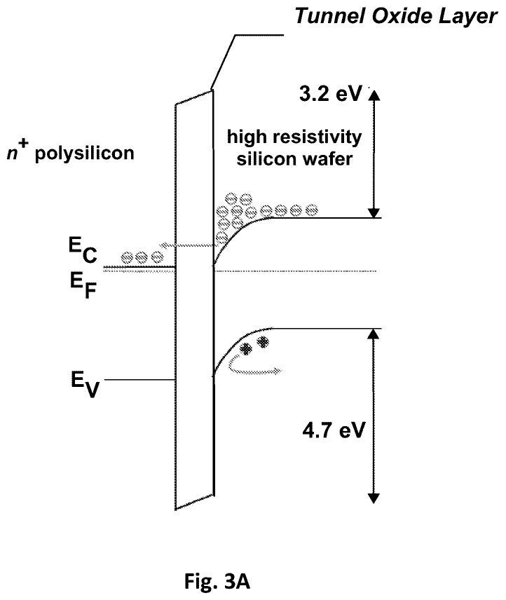

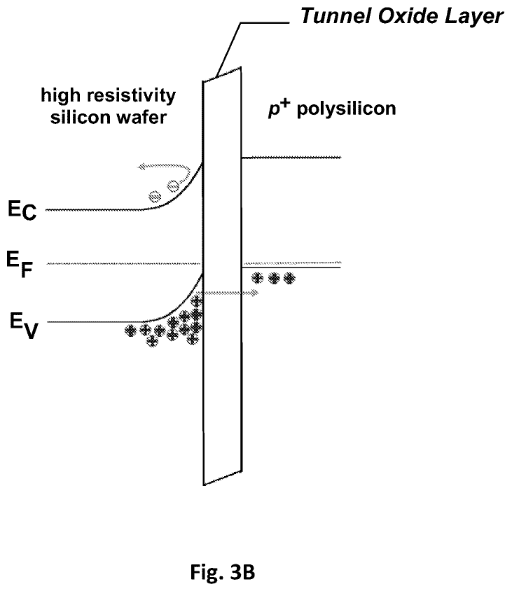

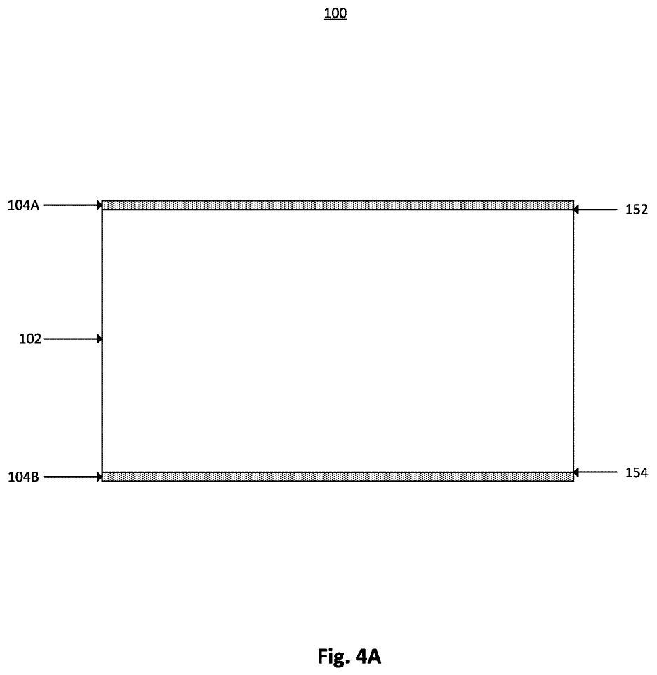

FIGS. 3A-3B illustrate example embodiments of band bending in the silicon layer by creating an accumulation layer of charge carriers in accordance with various embodiments of the present disclosure. In various embodiments, the doped polysilicon layers (e.g., first tunnel oxide layer and/or second tunnel oxide layer) may be configured to cause a band bending along at least a portion of the silicon layer (e.g., silicon wafer). In various embodiments, the lower doping level may be generated by the first tunnel oxide layer and/or the second tunnel oxide layer and may be configured to create an accumulation layer of charge carriers due to the different work function. In various embodiments, the different work function can result in a greater field effect passivation to reduce the minority carrier concentration at the silicon (SiOx) interface (e.g., first doped layer and/or second doped layer). In various embodiments, the first tunnel oxide layer and/or the second tunnel oxide layer may be configured to serve as a carrier-selective medium. The first tunnel oxide layer and/or the second tunnel oxide layer can be configured to serve as a carrier-selective medium by presenting one or more distinct tunneling barrier heights for one or more electrons to tunnel through and/or for one or more pin holes. In various embodiments, the first tunnel oxide layer and/or the second tunnel oxide layer may comprise different band offsets, such that the band offsets may be 4.7 eV for valence band and 3.2 eV for conduction band. In various embodiments, the band offsets may indicate an easier path for one or more electron to tunnel through rather than flowing through one or more pinhole. In various embodiments, the band offset values may be adjusted to perform the desired function.

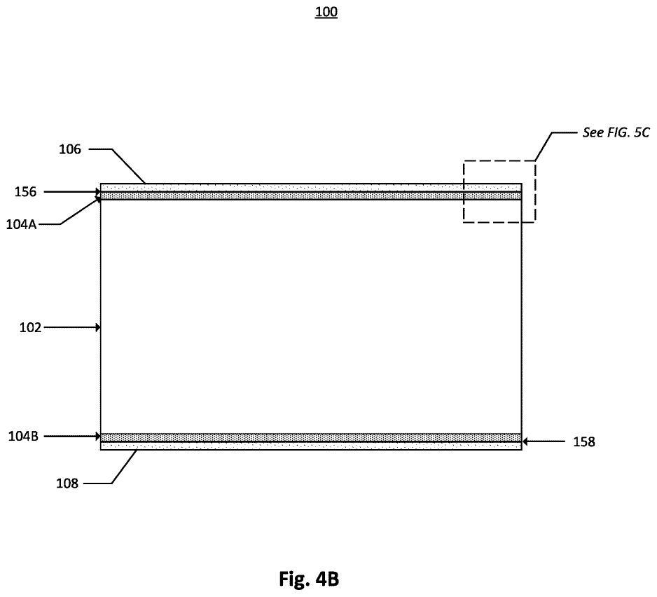

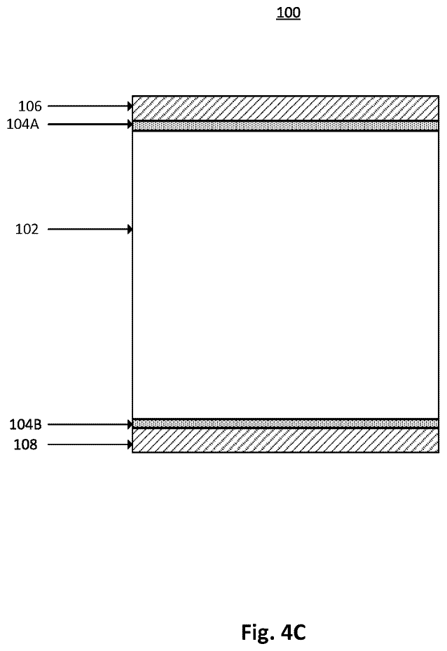

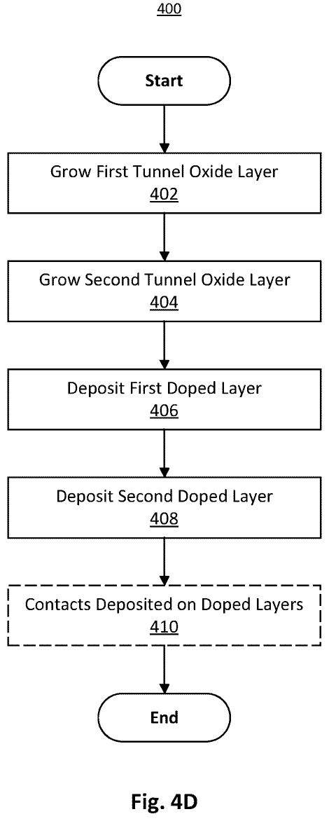

FIGS. 4A-4D illustrate example embodiments of the fabrication of a radiation detection device in accordance with various embodiments of the present disclosure. In various embodiments, the fabrication of a radiation detection device may begin with a silicon layer 102 (e.g., silicon wafer) being cleaned in a solution comprising at least piranha and hydrofluoric acid. In various embodiments, the silicon layer 102 may be cleaned in any solution necessary and/or at any predetermined temperature to achieve a desire function. In various embodiments, the silicon layer 102 may be immersed in a solution comprising 68 wt % nitric acid (HNO₃) heated at 100° C. In various embodiments, the first tunnel oxide layer (~1.5 nm) may be configured to be simultaneously grown on the first side of the silicon layer 102. In various embodiments, the first tunnel oxide layer may comprise a thickness between about 0.01 nm to 2 nm. In order to achieve a maximum depleted region, the dopant concentration on the higher-purity sides of the silicon layer should be minimized. Next, the doped n⁺ and p⁺ amorphous polysilicon layers (e.g., first doped layer and second doped layer) may be configured to be grown on a respective tunnel oxide layer (e.g., first tunnel oxide layer and second tunnel oxide layer). In various embodiments, a n⁺ phosphorous doped amorphous silicon layer (e.g., first doped layer 106) can be configured to be grown on a first side of the first tunnel oxide layer 104A and p⁺ boron doped amorphous silicon layer (e.g., second doped layer 108) can be configured to be grown on a second side (e.g., bottom side) of the second tunnel oxide layer 104B. In various embodiments, the n⁺ phosphorous doped amorphous silicon layer (e.g., first doped layer 106) and the p⁺ boron doped amorphous silicon layer (e.g., second doped layer 108) may be grown simultaneously and/or individually. In various embodiments, diluted B₂H₆ and PH₃ may be used as dopant precursors, mixing with SiH₄. In some embodiments, the radiation detection device 100 may be configured to be annealed at 800~900° C. for 5~30 min in a furnace (e.g., tube furnace, or the like). The furnace may comprise a nitrogen ambient to form the n⁺ and p⁺ polysilicon layers. In other embodiments, the radiation detection device may be configured to be annealed at 500~1200° C. for 5~30 min in a furnace (e.g., tube furnace, or the like). The furnace may comprise a nitrogen ambient to form the n⁺ and p⁺ polysilicon layers. This high temperature annealing may be used for solid-phase crystallization of the amorphous silicon films, as well as dopant activation in the resulting polysilicon.

With reference to FIG. 4D, an example flow chart illustrating a method 400 of fabrication is illustrated in accordance with various embodiments of the present disclosure. In various embodiments, after the cleaning of the silicon layer, a first tunnel oxide layer may be grown proximate to a first side of the silicon layer, see block 402. With reference to FIG. 4A, the first tunnel oxide layer 104A may comprise at least a first side and a second side. In various embodiments, the second side of the first tunnel oxide layer 104A may be grown on the first side of the silicon layer 102, such that the second side of the first tunnel oxide layer 104A at least partially contacts 152 the first side of the silicon layer. At block 404, a second tunnel oxide layer may be grown proximate to a second side of the silicon layer. With reference to FIG. 4A, the second tunnel oxide layer 104B may comprise at least a first side and a second side. In various embodiments, the first side of the second tunnel oxide layer 104B may be grown on the second side of the silicon layer 102, such that the first side of the second tunnel oxide layer 104B at least partially contacts 154 the second side of the silicon layer. In various embodiments, the first tunnel oxide layer 104A and the second tunnel oxide layer 104B may be grown separately. In various embodiments, the first tunnel oxide layer 104A and the second tunnel oxide layer 104B may be grown simultaneously.

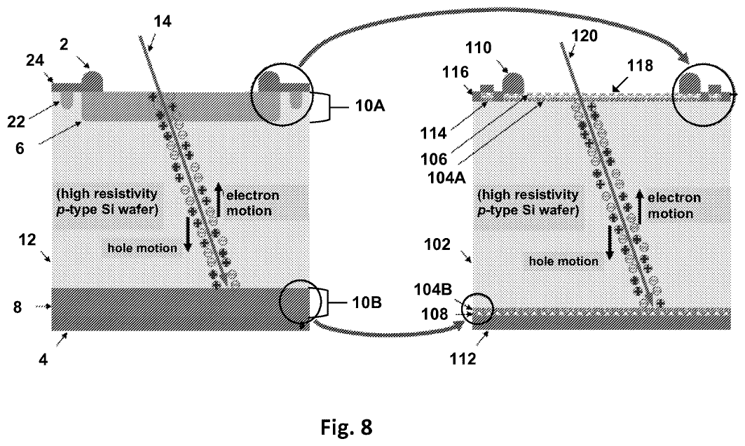

In various embodiments, chemically grown oxide layers (e.g., first tunnel oxide layer and/or second tunnel oxide layer) may comprise a low leakage current density, good stoichiometry, and thermal stability compared to thermally grown SiO₂ layers. The first tunnel oxide layer and/or the second tunnel oxide layer may be grown by either thermal oxidation, UV/ozone exposure, any chemical growth method, or a combination thereof. In various embodiments, a guard ring structure and a passivation layer on the detector side may be employed in order to reduce the surface leakage, as shown in FIG. 8. Due to the excellent passivation performance of the tunnel oxide layers with J₀ of ~5 fA/cm², the top aluminum contact layer may be patterned to minimize the metal coverage area and create more active areas (FIG. 8), which may allow for minimum energy loss of incident particle. In various embodiments, the n-type and p-type tunnel oxide layers on the detector side (e.g., first side) and the back side (e.g., second side) can be configured to generated charge carriers to be collected that contributed to the radiation detection pulse, which led to a higher energy resolution and lower noise level, compared to the conventional silicon junction detectors.

At block 406, a first doped layer may be configured to be disposed proximate to the first side of the first tunnel oxide layer 104A. With reference to FIG. 4B, the first doped layer 106 may comprise at least a first side and a second side. In various embodiments, the second side of the first doped layer 106 may be positioned proximate to the first side of the first tunnel oxide layer 104A, such that the second side of the first doped layer 106 at least partially contacts 156 the first side of the first tunnel oxide layer 104A. At block 408, a second doped layer 108 can be configured to be disposed proximate to the second side of the second tunnel oxide layer 104B. With reference to FIG. 4B, the second doped layer 108 may comprise at least a first side and a second side. In various embodiments, the first side of the second doped layer 108 can be configured to be positioned proximate to the second side of the second tunnel oxide layer 104B, such that the first side of the second doped layer 108 may at least partially contacts 158 the second side of the second tunnel oxide layer 104B. In various embodiments, the first doped layer 106 and the second doped layer 108 may be configured to be deposited on the respective tunnel oxide layers separately. In various embodiments, the first doped layer 106 and the second doped layer 108 may be configured to be deposited on the respective tunnel oxide layers simultaneously. At block 410, a front contact and a back contact may be disposed proximate to the respective doped layer, such that the front contact may be disposed proximate to the first side of first doped layer and the back contact may be disposed proximate to the second side of second doped layer. In various embodiments, the front contact and the back contact may be configured to be attached to the respective doped layers separately. In various embodiments, the front contact and the back contact may be configured to be attached to the respective doped layers simultaneously.

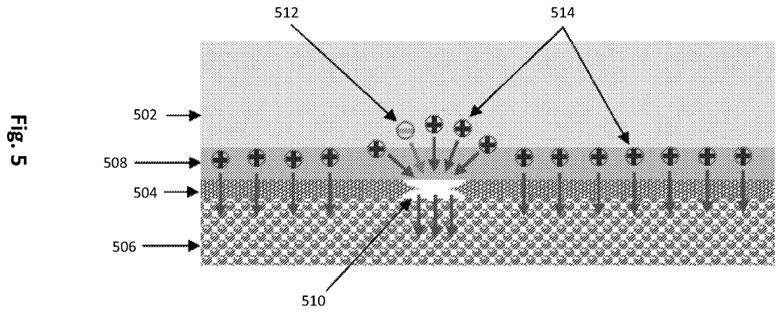

FIG. 5 illustrates an example pinhole generated within a radiation detection device in accordance with various embodiments of the present disclosure. In various embodiments, a pinhole 510 may be created beneath the lower most surface of the doped layer 508 in the tunnel oxide layer 504, such that electrons 512 may travel to the depleted area 506 (e.g., silicon layer). In various embodiments, the pinhole 512 may be configured to assist with the transportation of majority carriers from the first doped layer to the second doped layer. In other embodiments, the pinhole 510 may be configured to induce recombination by trapping one or more minority carrier. In various embodiments, the radiation detection device 500 may induce a pinhole 510 due to high-temperature annealing.

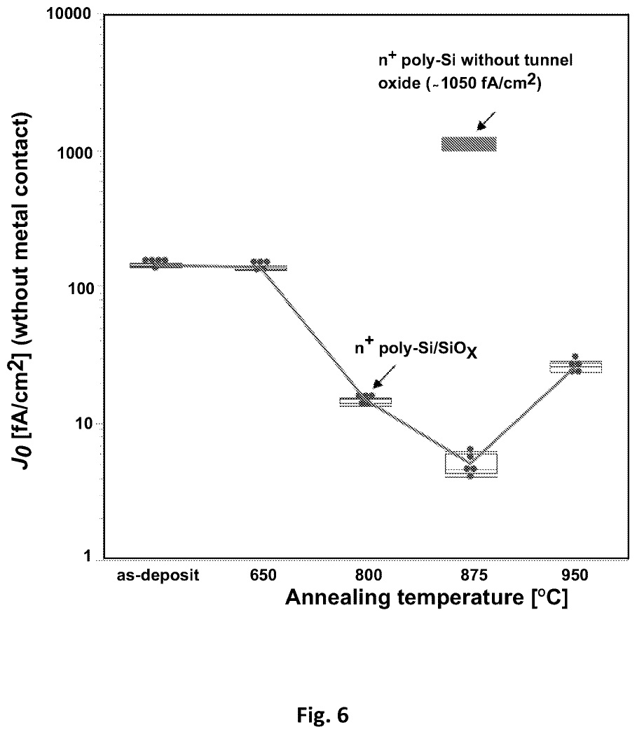

FIG. 6 graphically illustrates J₀ of n-type tunnel oxide layer as a function of annealing, including the J₀ without tunnel oxide layer temperature, in accordance with various embodiments of the present disclosure. In various embodiments, the radiation detection device may be annealed at a desired temperature between 0 and 30 minutes. In other embodiments, the radiation detection device may be annealed at a desired temperature for at least 30 minutes. In various embodiments, the annealing of a radiation detection device at 300° C.-650° C. may be insufficient to accomplish the solid phase crystallization of amorphous silicon (e.g., first doped layer and second doped layer) and activate the dopants. Thus, there may be no improvement in reducing the J₀ value of approximately 145 fA/cm². In various embodiments, the annealing of a radiation detection device at 800° C. can be configured to improve the passivation performance of the radiation detection device by lowering the J₀ value down to ~15 fA/cm². In various embodiments, the thermal budget of 875° C. may further enhance the passivation quality of the radiation detection device with an ultra-low J₀ value down to ~5 fA/cm². In an instance in which the annealing temperature may be increased to 950° C., the passivation performance may downgrade and a J₀ value may increase to around 25 fA/cm². In various embodiments, unproper pinholes and bigger pinholes (higher density) may be created at 950° C., such that more direct contacts between polysilicon and crystalline wafers, which may cause a higher recombination velocity.

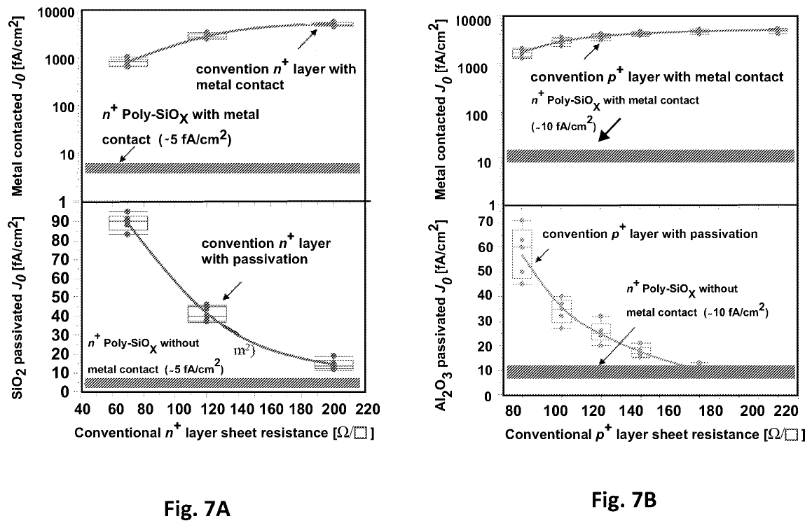

FIGS. 7A-7B illustrate conventional p-n junction versus the tunnel oxide layer of the current invention in accordance with various embodiments of the present disclosure. In various embodiments, the J₀ of conventional n⁺ layer passivated with a ~10 nm thermally-grown SiO₂ (J₀ₙ₋ₚₐₛₛ) (e.g., passivated with at least one tunnel oxide layer) may decrease the J₀ value from about 90 to 20 fA/cm² as its sheet resistance may be increase from 70 to 200 ohm per square (Ω/□), due to less Auger recombination within n⁺ layer and lower carrier recombination velocity at the surface. In various embodiments, the J₀ of metal contact area on conventional n⁺ layer (J₀ₙ₋ₘₑₜₐₗ) without one or more tunnel oxide layers may rapidly increase from around 900 to over 5000 fA/cm², resulting from higher metal-induced recombination due to less shielding for minority carriers. At the metal contact areas, one or more metal atoms may occupy substitutional lattice positions and act as one or more deep impurity, such that the one or more deep impurity may introduce energy levels near the middle of the forbidden gap. Hence, the traditional radiation devices comprise active traps for charge carriers. These trapping centers captured holes or electrons for long period of time and prevent them from contributing to the radiation detection pulse. The one or more deep impurity at the metal contact regions may behave as recombination centers and may capture both electrons and holes to cause them to annihilate. In various embodiments, the n-type tunnel oxide passivating layer (e.g., first tunnel oxide layer and/or second tunnel oxide layer) can be configured to optimized J₀₋ₚₐₛₛ of ~5 fA/cm² without one or more metal contact, compared to the conventional n⁺ layer of ~20 fA/cm². In various embodiments, the n-type tunnel oxide passivating (e.g., first tunnel oxide layer and/or second tunnel oxide layer) can be configured to maintain an ultra-low J₀₋ₘₑₜₐₗ of ~5 fA/cm² because the first tunnel oxide layer and/or the second oxide layer may block one or more minority carriers from contacting with a metal surface (e.g., front contact and/or back contact). As depicted in FIG. 7A, the J₀ₙ₋ₘₑₜₐₗ of conventional n⁺ layers (1000~6000 fA/cm²) can be configured to be astronomically larger than the n⁺ layers J₀ₙ₋ₘₑₜₐₗ value of the present invention.

In various embodiments, the passivated p⁺ layers of the current invention (e.g., first tunnel oxide layer and/or second oxide layer) may comprise an effect passivation function from the atomic-layer deposited Al₂O₃ layer with negative charges can be configured to reduce the J₀ values (J₀ₚ₋ₚₐₛₛ), such that the J₀ values were reduced from ~60 fA/cm² to ~10 fA/cm². In various embodiments, the first tunnel oxide layer and/or the second can be configured to increase the sheet resistance from 80 to 210Ω/□. The sheet resistance increase may be due to less Auger recombination within the p⁺ layer, and lower carrier recombination velocity at the silicon surface may result from lower doping level of higher sheet resistance. When contacted with metal electrode, the conventional p⁺ layers suffered from significant metal-induced recombination due to higher sheet resistance and less shielding for minority carriers at the contact interface. The increase of metal-induced recombination may lead to an increasing J₀ₚ₋ₘₑₜₐₗ values from 1500 to over 5000 fA/cm², as displayed in FIG. 7B. In various embodiments, the experimental J₀ values of the present invention for the optimized p-type tunnel oxide layer (e.g., first tunnel oxide layer and/or second tunnel oxide layer) may be 10 fA/cm². The experimental J₀ values for the optimized n-type tunnel oxide layer may be in a comparable range of the p-type tunnel oxide layer. In various embodiments, the low J₀ₚ₋ₚₐₛₛ of ~10 fA/cm² can be maintained when the radiation detection device is contacted with one or more metal electrode due to the blocking function of tunnel oxide passivating contact (e.g., first tunnel oxide layer and/or second tunnel oxide layer) for the minority carriers.

FIG. 8 illustrates a cross-sectional view of a conventional radiation detection device versus the present invention in accordance with various embodiments of the present disclosure. In various embodiments, a conventional radiation detection device may comprise two dead regions 10A, 10B, such that the two dead regions are n+ layer 6 and the p+ layer 8. In the depicted embodiments, the radiation detection device of the present invention can be configured to replace the dead regions with the first tunnel oxide layer 104A, the first doped layer 106, the second tunnel oxide layer 104B, and/or the second doped layer 108, such that the tunnel oxide layers can improve the passivation of the radiation detection device. In various embodiments, the first doped layer 106, first tunnel oxide layer 104A, second tunnel oxide layer 104B, and/or the second doped layer 108 can be configured to assist with the prevention of electron recombination as described above. In various embodiments, the radiation detection device of the present application may comprise a passivation layer consisting of at least a tunnel oxide layer and a doped layer. In some embodiments, the passivation layer may further comprise a guard ring.

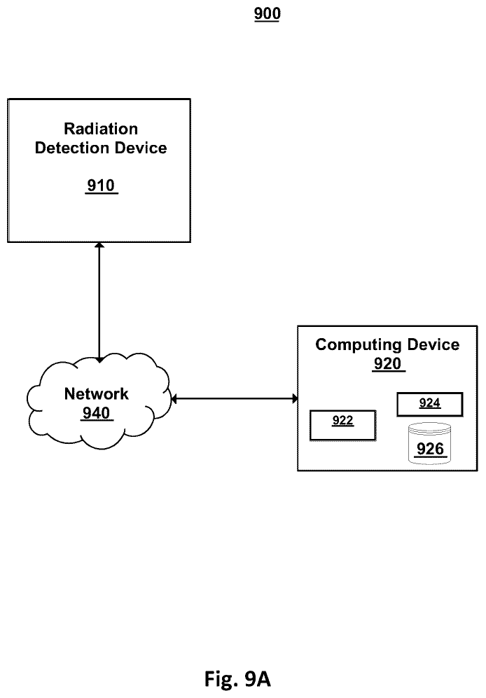

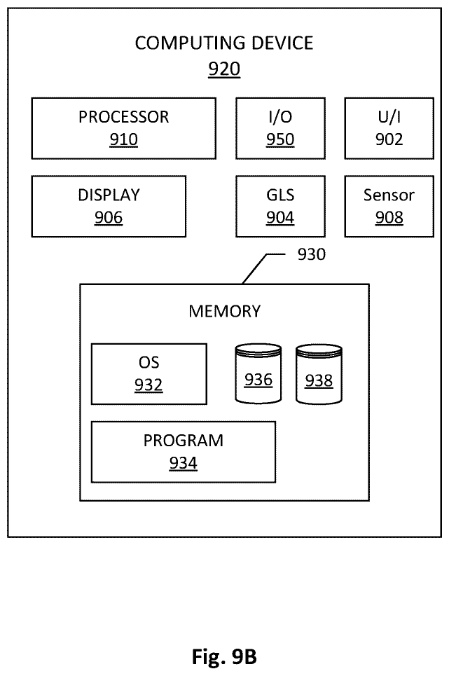

FIG. 9A shows an example system 900 that may implement certain aspects of the present disclosure. The components and arrangements shown in FIG. 9A are not intended to limit the disclosed embodiments as the components used to implement the disclosed processes and features may vary. As shown in FIG. 9A, in some implementations the system 900 may include a radiation detection device 910, a computing device 920, and a network 940. The radiation detection device 910 may be in wireless communication with the computing device 920. In some embodiments, the radiation detection device 910 may be a portion of the computing device 920. In other embodiments, the computing device 920 may be a portion of the radiation detection device 910. Additionally, computing device 920 may include one or more processors 922, one or more transceivers 924, and one or more databases 926.

As non-limiting examples, the network 940 may include a network of interconnected computing devices such as a local area network (LAN), Wi-Fi, Bluetooth, or other type of network and may be connected to an intranet or the Internet, among other things. The computing device 920 may include one or more physical or logical devices (e.g., servers) or drives and may be implemented as a single server or a bank of servers (e.g., in a “cloud”). An example computer architecture with reference to FIG. 9B is described below. The example computer architecture may be used to implement computing device 920.

In certain implementations according to the present disclosure, the computing device 920 may be in communication with a radiation detection device in order to perform a desired function. In some examples, the computing device 920 may comprise, for example, a cell phone, a smart phone, a tablet computer, a laptop computer, a desktop computer, a sever, or other electronic device. The computing device 920 may be a single server, for example, or may be configured as a distributed, or “cloud,” computer system including multiple servers or computers that interoperate to perform one or more of the processes and functionalities associated with the disclosed embodiments. In some embodiments, the computing device 920 may further include a peripheral interface, a transceiver, a mobile network interface in communication with processor 910, a bus configured to facilitate communication between the various components of the computing device 920, and a power source configured to power one or more components of the computing device 920.

An example embodiment of a computing device 920 is shown in more detail in FIG. 9B. As shown, computing device 920 may include processor 910, input/output (“I/O”) device 950, memory 930 containing an operating system (“OS”) 932 and program 934. Computing device 920 may also have one or more processors 910, geographic location sensor (“GLS”) 904 for determining the geographic location of computing device 920, display 906 for displaying content such as text messages, items, and selectable buttons/icons/links, sensor(s) 908 for obtaining environmental data, and user interface (“U/I”) device 902 for receiving user input data, such as data representative of a click, a scroll, a tap, a press, or typing on an input device that can detect tactile inputs. According to some embodiments, U/I device 902 may include some or all of the components described with respect to I/O device 950 above.

Memory 930 may include one or more memory devices that store data and instructions used to perform one or more features of the disclosed embodiments. Memory 930 may also include any combination of one or more databases controlled by memory controller devices (e.g., server(s), etc.) or software, such as document management systems, Microsoft™ SQL databases, SharePoint™ databases, Oracle™ databases, Sybase™ databases, or other relational databases. Memory 930 may include software components that, when executed by processor 910, perform one or more processes consistent with the disclosed embodiments. In some embodiments, memory 930 may include one or more databases 936, 938 for storing related data to enable the computing device 920 to perform one or more of the processes and functionalities associated with the disclosed embodiments.

A peripheral interface may include the hardware, firmware, and/or software that enables communication with various peripheral devices, such as media drives (e.g., magnetic disk, solid state, or optical disk drives), other processing devices, or any other input source used in connection with the instant techniques. In some embodiments, a peripheral interface may include a serial port, a parallel port, a general-purpose input and output (GPIO) port, a game port, a universal serial bus (USB), a micro-USB port, a high definition multimedia (HDMI) port, a video port, an audio port, a Bluetooth™ port, a near-field communication (NFC) port, another like communication interface, or any combination thereof.

In some embodiments, a transceiver may be configured to communicate with compatible devices and ID tags when they are within a predetermined range. The transceiver may be compatible with one or more of: radio-frequency identification (RFID), near-field communication (NFC), Bluetooth™, low-energy Bluetooth™ (BLE), WiFi™, ZigBee™, ambient backscatter communications (ABC) protocols or similar technologies.

A mobile network interface may provide access to a cellular network, the Internet, or another wide-area network. In some embodiments, a mobile network interface may include hardware, firmware, and/or software that allows processor(s) 910 to communicate with other devices via wired or wireless networks, whether local or wide area, private or public, as known in the art. A power source may be configured to provide an appropriate alternating current (AC) or direct current (DC) to power components.

As described above, the computing device 920 may be configured to remotely communicate with one or more other devices, such as radiation detection device 910, network 940, and/or other external devices.

Processor 910 may include one or more of a microprocessor, a microcontroller, a digital signal processor, a co-processor or the like or combinations thereof capable of executing stored instructions and operating upon stored data. Memory 930 may include, in some implementations, one or more suitable types of memory (e.g. such as volatile or non-volatile memory, a random access memory (RAM), a read only memory (ROM), a programmable read-only memory (PROM), an erasable programmable read-only memory (EPROM), an electrically erasable programmable read-only memory (EEPROM), one or more magnetic disks, one or more optical disks, one or more floppy disks, one or more hard disks, one or more removable cartridges, a flash memory, a redundant array of independent disks (RAID), and the like), for storing files including an operating system, one or more application programs (including, for example, a web browser application, a widget or gadget engine, and or other applications, as necessary), executable instructions and data. In one embodiment, the processing techniques described herein are implemented as a combination of executable instructions and data within memory 930.

Processor 910 may be one or more known processing devices, such as a microprocessor from the Pentium™ family manufactured by Intel™ or the Turion™ family manufactured by AMD™. Processor 910 may constitute a single core or multiple core processor that executes parallel processes simultaneously. Processor 910 may be a single core processor, for example, that is configured with virtual processing technologies. In certain embodiments, processor 910 may use logical processors to simultaneously execute and control multiple processes. Processor 910 may implement virtual machine technologies, or other similar known technologies to provide the ability to execute, control, run, manipulate, store, etc. multiple software processes, applications, programs, etc. One of ordinary skill in the art would understand that other types of processor arrangements could be implemented that provide for the capabilities disclosed herein.

The computing device 920 may include one or more storage devices configured to store information used by processor 910 (or other components) to perform certain functions related to the disclosed embodiments. In one example, the computing device 920 may include memory 930 that includes instructions to enable processor 910 to execute one or more applications, such as server applications, network communication processes, and any other type of application or software known to be available on computer systems. Alternatively, the instructions, application programs, etc. may be stored in an external storage or available from a memory over a network. The one or more storage devices may be a volatile or non-volatile, magnetic, semiconductor, tape, optical, removable, non-removable, or other type of storage device or tangible computer-readable medium.

In one embodiment, the computing device 920 may include memory 930 that includes instructions that, when executed by processor 910, perform one or more processes consistent with the functionalities disclosed herein. Methods, systems, and articles of manufacture consistent with disclosed embodiments are not limited to separate programs or computers configured to perform dedicated tasks. The computing device 920 may include memory 930 including one or more programs 934, for example, to perform one or more functions of the disclosed embodiments. Moreover, processor 910 may execute one or more programs 934 located remotely from the computing device 920. For example, the computing device 920 may access one or more remote programs 934, that, when executed, perform functions related to disclosed embodiments.

The computing device 920 may also be communicatively connected to one or more memory devices (e.g., databases (not shown)) locally or through a network. The remote memory devices may be configured to store information and may be accessed and/or managed by the computing device 920. By way of example, the remote memory devices may be document management systems, Microsoft™ SQL database, SharePoint™ databases, Oracle™ databases, Sybase™ databases, or other relational databases. Systems and methods consistent with disclosed embodiments, however, are not limited to separate databases or even to the use of a database.

The computing device 920 may also include one or more I/O devices 950 that may include one or more interfaces (e.g., transceivers) for receiving signals or input from radiation detection device(s) and providing signals or output to one or more devices that allow data to be received and/or transmitted by the computing device 920. The computing device 920 may include interface components, for example, which may provide interfaces to one or more input devices, such as one or more keyboards, mouse devices, touch screens, track pads, trackballs, scroll wheels, digital cameras, microphones, sensors, and the like, that enable the computing device 920 to receive data from one or more users.

While the computing device 920 has been described as one form for implementing the techniques described herein, those having ordinary skill in the art will appreciate that other, functionally equivalent techniques may be employed. As is known in the art, some or all of the functionality implemented via executable instructions may also be implemented using firmware and/or hardware devices such as, for example, application specific integrated circuits (ASICs), programmable logic arrays, state machines, etc. Furthermore, other implementations of the computing device may include a greater or lesser number of components than those illustrated.

While certain embodiments of the disclosed technology have been described in connection with what is presently considered to be the most practical embodiments, it is to be understood that the disclosed technology is not to be limited to the disclosed embodiments, but on the contrary, is intended to cover various modifications and equivalent arrangements included within the scope of the appended claims. Although specific terms are employed herein, they are used in a generic and descriptive sense only and not for purposes of limitation.

This written description uses examples to disclose certain embodiments of the disclosed technology, including the best mode, and to enable any person skilled in the art to practice certain embodiments of the disclosed technology, including making and using any devices or systems and performing any incorporated methods. The patentable scope of certain embodiments of the disclosed technology is defined in the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. A radiation detection system configured for detecting radiation comprising:
a silicon layer having at least a first side and a second side;
a first tunnel oxide layer having at least a first side and a second side, wherein the second side of the first tunnel oxide layer is disposed proximate to the first side of the silicon layer; and
a first doped layer disposed proximate to the first side of the first tunnel oxide layer.

2. The radiation detection system of claim 1, wherein at least one of the first tunnel oxide layer or the first doped layer is configured to be thermally activated by thermal annealing in a temperature range from approximately 500° C. to approximately 1200° C.

3. The radiation detection system of claim 2 further comprising:
a front contact disposed proximate to the first side of the first doped layer.

4. The radiation detection system of claim 3, wherein the radiation detection device is configured to achieve an emitter saturation current density of approximately 1000 fA/cm².

5. The radiation detection system of claim 4 further comprising:
a second tunnel oxide layer having at least a first side and a second side, wherein the first side of the second tunnel oxide layer is disposed proximate to the second side of the silicon layer; and
a second doped layer having at least a first side and a second side, wherein the first side of the second doped layer is disposed proximate to the second side of the second tunnel oxide layer;
wherein:
the first side of the silicon layer is disposed vertically opposite of the second side of the silicon layer; and
the first doped layer is configured to be a polysilicon layer.

6. The radiation detection system of claim 5, wherein at least one of:
the polysilicon layer is configured to cause band bending in the silicon layer by creating an accumulation layer of charge carriers;
the second doped layer is configured to be a polysilicon layer; or
at least one of the second doped layer or the second tunnel oxide layer is configured to be thermally activated by thermal annealing in a temperature range from approximately 500° C. to approximately 1200° C.

7.-10. (canceled)

11. The radiation detection system of claim 6 further comprising:
a back contact disposed proximate to the second side of the second doped layer.

12. The radiation detection system of claim 11, wherein:
the second doped layer comprises a n-type dopant configured to be a phosphorous-dopant; or
the second doped layer comprises a p-type dopant configured to be a boron-dopant.

13. (canceled)

14. The radiation detection system of claim 12, wherein the second tunnel oxide layer is configured to reduce a charge carrier loss.

15. The radiation detection system of claim 14, wherein the second tunnel oxide layer is configured to transport majority charge carriers via tunneling and block minority charge carriers.

16. The radiation detection system of claim 12, wherein the second tunnel oxide layer is configured to reduce metal-induced electron recombination beneath a front contact and a back contact.

17. The radiation detection system of claim 12, wherein the second tunnel oxide layer comprises a uniform thickness equal to or less than about 2 nm.

18.-67. (canceled)

68. The radiation detection system of claim 11 further comprising:
a computing device.

69.-85. (canceled)

86. The radiation detection system of claim 6, wherein the first tunnel oxide layer and the second tunnel oxide layer comprise equal thicknesses.

87. (canceled)

88. The radiation detection system of claim 68, wherein the second doped layer comprises a thickness equal to or less than about 30 nm.

89. The radiation detection system of claim 68, wherein:
the first doped layer comprises a n-type dopant configured to be a phosphorous-dopant; or
the first doped laver comprises a p-type dopant configured to be a boron-dopant.

90.-91. (canceled)

92. The radiation detection system of claim 6, wherein the first tunnel oxide layer is configured to transport majority charge carriers via tunneling and block minority charge carriers.

93. The radiation detection system of claim 68, wherein the first tunnel oxide layer is configured to reduce metal-induced electron recombination beneath a front contact and a back contact.

94. The radiation detection system of claim 68, wherein the first doped layer comprises at least a first side and a second side, wherein the second side of the first doped layer is disposed proximate to the first side of the first tunnel oxide layer.

95.-99. (canceled)
